(19) United States
(12) Patent Application Publication
(10) Pub. No.: US 2014/0061617 A1
(43) Pub. Date: Mar. 6, 2014

(54) METHOD AND APPARATUS FOR INTEGRATING AN INFRARED (HR) PHOLOVOLTAIC CELL ON A THIN PHOTOVOLTAIC CELL

(71) Applicants: Franky So, Gainesville, FL (US); Do Young Kim, Gainesville, FL (US); Bhabendra K. Pradhan, Marietta, GA (US)

(72) Inventors: Franky So, Gainesville, FL (US); Do Young Kim, Gainesville, FL (US); Bhabendra K. Pradhan, Marietta, GA (US)

(73) Assignee: UNIVERSITY OF FLORIDA RESEARCH FOUNDATION, INC., Gainesville, FL (US)

(21) Appl. No.: 14/009,979

(22) PCT Filed: Apr. 3, 2012
(86) PCT No.: PCT/US12/32008

§ 371 Date: Nov. 18, 2013

(30) Foreign Application Priority Data
Apr. 5, 2011 (US) 61472088

(51) Int. Cl. H01L 51/52

(52) U.S. Cl. CPC H01L 51/5271
USPC 257/40; 438/29

(57) ABSTRACT

Embodiments of the subject invention relate to a method and apparatus for providing an at: least partially transparent one-side emitting OLED. The at least partially transparent one-side emitting OLED can include a mirror, such as a mirror substrate, substrate with a transparent anode and a transparent cathode. The mirror can allow at least a portion of the visible spectrum of light to pass through, while also reflecting at least another portion of the visible spectrum of light. The mirror can reflect at least a portion of the visible light emitted by a light emitting layer of the OLED incident on a first surface of the mirror, while allowing another portion of the visible light incident on a second surface of the mirror to pass through the mirror.

### CROSS-REFERENCE TO RELATED APPLICATION

The present application claims the benefit of U.S. Provisional Application Ser. No. 61/472,088, filed Apr. 5, 2011, the disclosure of which is hereby incorporated by reference herein in its entirety, including any figures, tables, or drawings.

### BACKGROUND OF INVENTION

Organic light-emitting devices (OLEDs) incorporate organic materials and emit light. A transparent OLED includes a top electrode and a bottom electrode, both of which are transparent electrodes. A one-sided OLED, which can be either conventional bottom-emitting or top-emitting, generally includes a reflective electrode and a transparent electrode. In both cases, an organic light-emitting layer is included between the electrodes.

### BRIEF SUMMARY

Embodiments of the subject invention relate to a method and apparatus for providing an at least partially transparent one-side emitting OLED. By at least partially transparent, it is meant that the OLED allows at least a portion of the visible spectrum to pass through. The at least partially transparent one-side emitting OLED can include a minor, such as a mirror substrate, substrate with a transparent anode and a transparent cathode. The mirror can allow at least a portion of the visible spectrum of light to pass through, while also reflecting at least another portion of the visible spectrum of light. For example, the mirror can reflect at least a portion of the visible light emitted by a light emitting layer (e.g. an organic light emitting layer) of the OLED incident on a first surface of the mirror, while allowing another portion of the visible light incident on a second surface of the mirror to pass through the mirror. In an embodiment, the OLED can include a dielectric stack minor, an indium tin oxide (ITO) bottom anode electrode, and a Mg:Ag top cathode electrode.

Embodiments of the subject invention also pertain to a method and apparatus for providing a lighting window including an at least partially transparent one-side emitting OLED. When making a window using an at least partially transparent one-side emitting OLED, it is possible to see outside, such as during the day, and have the one-side emitting OLED act as a lighting source, such as at night, because the OLED light is primarily emitted in only one direction. This can be accomplished by including a mirror which reflects at least a portion of the visible light emitted by an organic light emitting layer of the OLED. The window can be arranged such that the one direction in which the OLED emits is toward the inside of a building or other structure and not out into the environment.

In an embodiment of the subject invention, an at least partially transparent and one-side emitting OLED can incorporate a dielectric stack mirror substrate. The OLED can further include a transparent anode electrode, an organic light-emitting layer, and a transparent cathode electrode. In a specific embodiment, the dielectric stack mirror substrate can include alternating layers of Ta₂O₅ and SiO₂. In a particular embodiment, an OLED can include: a glass substrate; a dielectric stack mirror on the glass substrate, wherein the dielectric stack mirror incorporates alternating layers of Ta₂O₅ and SiO₂; a transparent anode electrode on the dielectric stack mirror, wherein the transparent anode electrode includes ITO; a hole transporting layer on the transparent anode electrode; an organic light-emitting layer on the hole transporting layer; and a transparent cathode electrode on the organic light-emitting layer, wherein the transparent cathode electrode includes a Mg:Ag/Alq3 stack layer, wherein the Mg:Ag layer has a thickness of less than 30 nm, and wherein Mg and Ag are present in a ratio of 10:1 (Mg:Ag), and wherein the Alq3 layer has a thickness of from 0 nm to 200 nm.

In a further embodiment of the subject invention, a lighting window can include an at least partially transparent and one-side emitting OLED.

In yet a further embodiment of the subject invention, a method of fabricating an at least partially transparent and one-side emitting OLED can include: forming a mirror; forming a transparent anode electrode on the mirror; forming an organic light-emitting layer on the transparent anode electrode; and forming a transparent cathode electrode on the organic light-emitting layer. The mirror can be, for example, a dielectric stack mirror, wherein the dielectric stack mirror includes alternating layers of two dielectric materials having different refractive indexes.

### BRIEF DESCRIPTION OF DRAWINGS

FIGS. 1A and 1B show the operating principle in daytime (FIG. 1A) and nighttime (FIG. 1B) of a lighting window according to an embodiment of the subject invention.

FIG. 2A shows a cross-sectional view of a dielectric stack mirror that can be incorporated into an OLED according to an embodiment of the subject invention.

FIG. 2B shows a transmittance spectrum for the dielectric stack mirror of FIG. 2A.

FIG. 3A shows a transparent image as seen through a transparent one-side emitting OLED according to an embodiment of the subject invention.

FIG. 3B shows a cross-sectional view of an OLED according to an embodiment of the subject invention.

FIG. 3C shows current density and luminescence vs. voltage for an OLED according to an embodiment of the subject invention.

FIG. 3D shows current efficiency vs. current density for an OLED according to an embodiment of the subject invention.

### DETAILED DISCLOSURE

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present. When the term “directly on” is used herein, when referring to layers, regions, patterns, or structures, it is understood that the layer, region, pattern or structure is directly on another layer or structure, such that no intervening layers, regions, patterns, or structures are present.

When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

When the term “at least partially transparent” is used herein, in conjunction with the term “OLED” (e.g., “an at least partially transparent one-side emitting OLED”, “an at least partially transparent OLED”), it is understood that the OLED, which may include a mirror and/or a mirror substrate, allows at least a portion of the visible spectrum of light to pass through the OLED. When the term “transparent” is used herein, in conjunction with the term “anode”, “cathode”, or “electrode”, it is understood that the anode, cathode, or electrode allows the light produced by the light emitting layer to pass through the anode, cathode, or electrode without significant reflection.

Embodiments of the subject invention relate to a method and apparatus for providing an at least partially transparent one-side emitting OLED. The at least partially transparent one-side emitting OLED can include a mirror substrate with a transparent anode electrode and a transparent cathode electrode. The mirror can allow at least a portion of the visible spectrum of light to pass through while also reflecting at least another portion of the visible spectrum of light. For example, the minor can reflect at least a portion of the visible light emitted by a light emitting layer (e.g., an organic light emitting layer) of the OLED. In an embodiment, the OLED can include a dielectric stack mirror, an indium tin oxide (ITO) bottom anode, electrode and a Mg:Ag top cathode electrode.

Embodiments of the subject invention also pertain to a method and apparatus for providing a lighting window including an at least partially transparent one-side emitting OLED. When making a window using an at least partially transparent one-side emitting OLED, it is advantageously possible to see outside, such as during the day, and have the one-side emitting OLED act as a lighting source, such as at night, because the OLED light is primarily emitted in only one direction. The window can be arranged such that the one direction in which the OLED emits is into a building or other structure and not out into the environment.

In an embodiment of the subject invention, an at least partially transparent and one-side emitting OLED can incorporate a minor substrate, such as a dielectric mirror substrate. The OLED can further include a transparent anode electrode, an organic light-emitting layer, and a transparent cathode electrode. In a specific embodiment, the mirror can be a dielectric stack mirror and can include alternating layers of Ta₂O₅ and SiO₂. In a particular embodiment, an OLED can include: a glass substrate; a dielectric stack minor on the glass substrate, wherein the dielectric stack mirror incorporates alternating layers of Ta₂O₅ and SiO₂; a transparent anode electrode on the dielectric stack minor, wherein the transparent anode electrode includes ITO; a hole transporting layer on the transparent anode; an organic light-emitting layer on the hole transporting layer; and a transparent cathode electrode on the organic light-emitting layer, wherein the transparent cathode electrode includes a Mg:Ag/Alq3 stack layer, wherein the Mg:Ag layer has a thickness of less than 30 nm, and wherein Mg and Ag are present in a ratio of 10:1 (Mg:Ag), and wherein the Alq3 layer has a thickness of from 0 nm to 200 nm.

In a further embodiment of the subject invention, a lighting window can include an at least partially transparent one-side emitting OLED.

In yet a further embodiment of the subject invention, a method of fabricating an at least partially transparent and one-side emitting OLED can include: forming a mirror; forming a transparent anode on the minor; forming an organic light-emitting layer on the transparent anode; and forming a transparent cathode on the organic light-emitting layer. The mirror can be, for example, a dielectric stack mirror, wherein the dielectric stack minor includes alternating layers of two dielectric materials having different refractive indexes.

A lighting window incorporating an at least partially transparent one-side emitting OLED as described herein can be transparent to light have a certain wavelength or wavelengths, such that it is possible to see outside in daytime, while also being a source of lighting when it is dark outside. The OLED light is emitted in one direction, and the lighting window can be arranged such that the light is emitted into a building or other structure and not into the environment. In embodiments, the at least partially OLED may be transparent to a portion of the visible spectrum of light, while reflecting another portion of the visible spectrum of light. The OLED of the lighting window can include: a light emitting layer (e.g., an organic light emitting layer) which emits light having a wavelength in a given range of the visible spectrum; and a mirror that is reflective of at least a portion of the light emitted by the light emitting layer of the OLED. The mirror can also be transparent to at least a portion of the visible spectrum of light not emitted by the OLED.

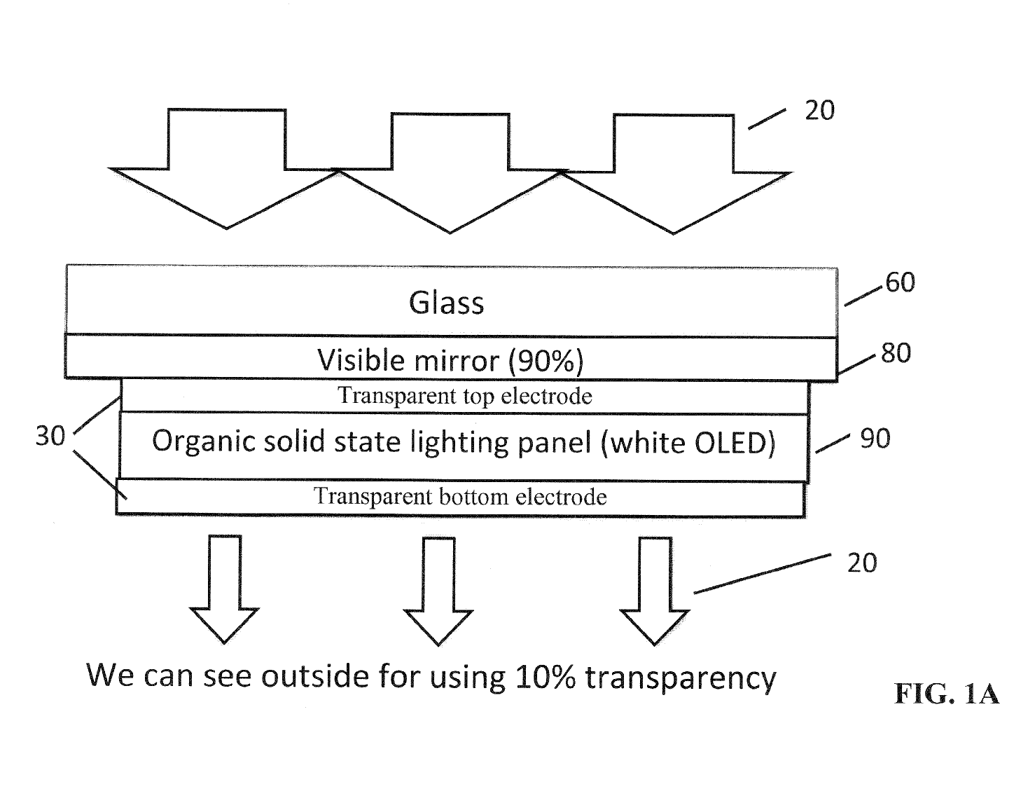

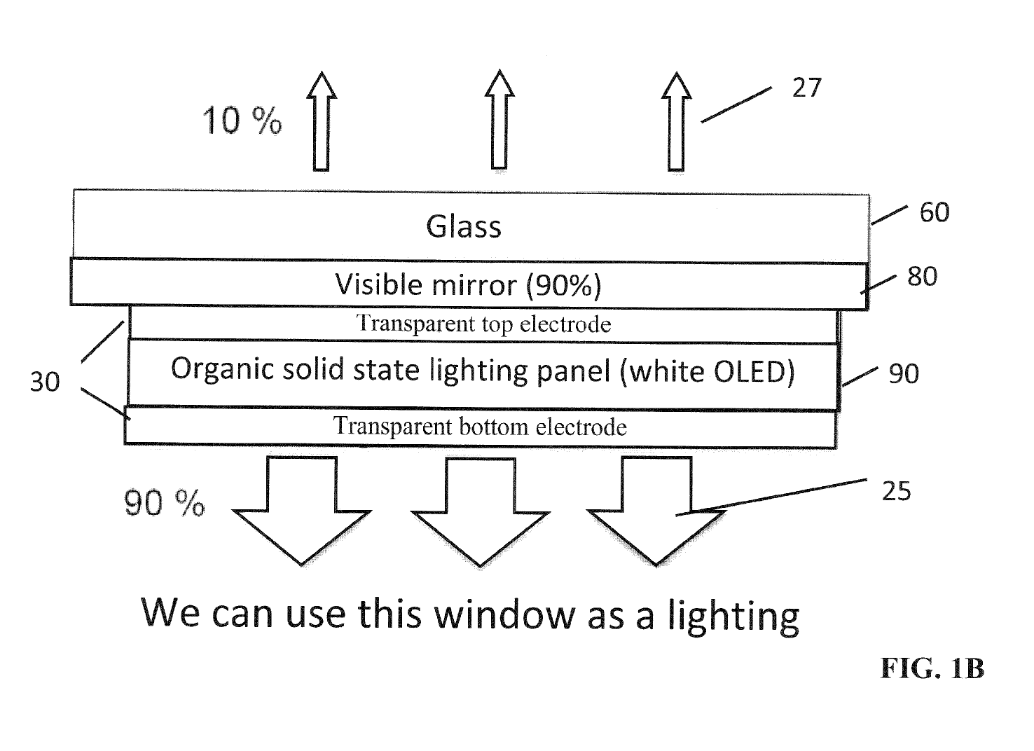

Referring to FIG. 1A, incident light 20, for example from the outside environment, can be incident on the glass substrate, and a portion of the incident light can travel through the apparatus such that the apparatus is at least partially transparent to visible light 20 and the apparatus can be used for viewing the outside environment from inside, e.g., during the day. Referring to FIG. 1B, the apparatus can be used to generate light (25, 27), e.g., at night when it is dark outside, a large percentage of which (about 90% or >90%) is transmitted in one direction 25, while only a small fraction (about 10% or <10%) is lost in the opposite direction 27. In this way, as a large portion of the light is transmitted in one direction, we refer to the OLED as a one-sided OLED. The apparatus can be positioned such that a vast majority of the light produced 25 is provided in a desirable location (e.g., inside a building or structure or towards an area needing light outside) while only a small portion is lost in the opposite direction 27. The apparatus can optionally include a glass substrate 60 and/or one or more transparent electrode layers 30. The apparatus can also include a visible mirror 80 and an organic light-emitting layer 90. In a specific embodiment, the visible mirror can allow infrared (IR) radiation to pass through the mirror.

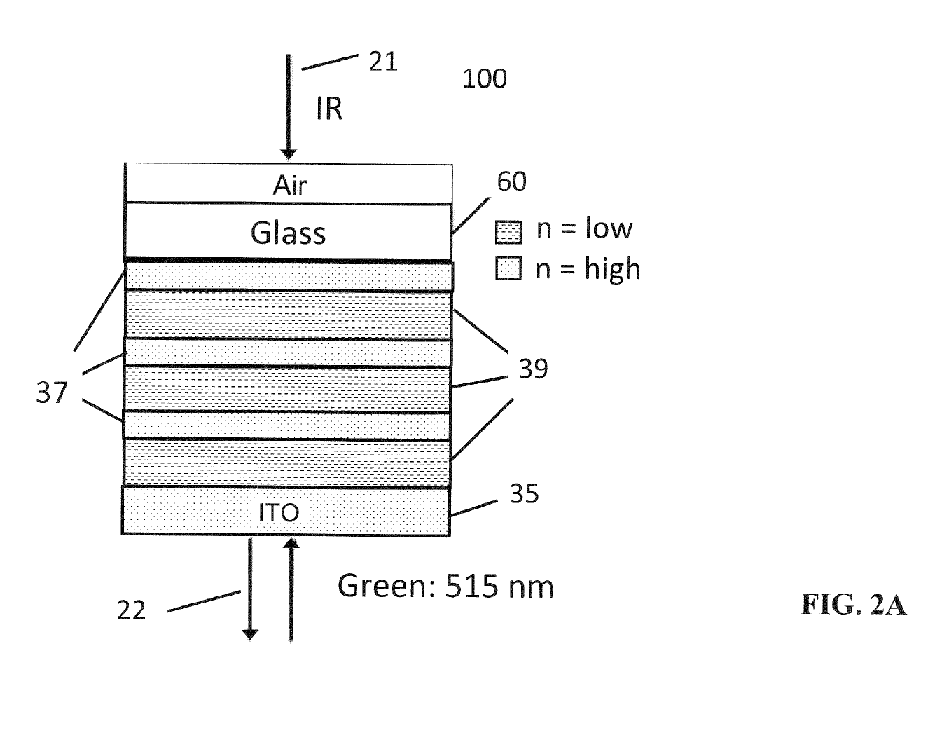

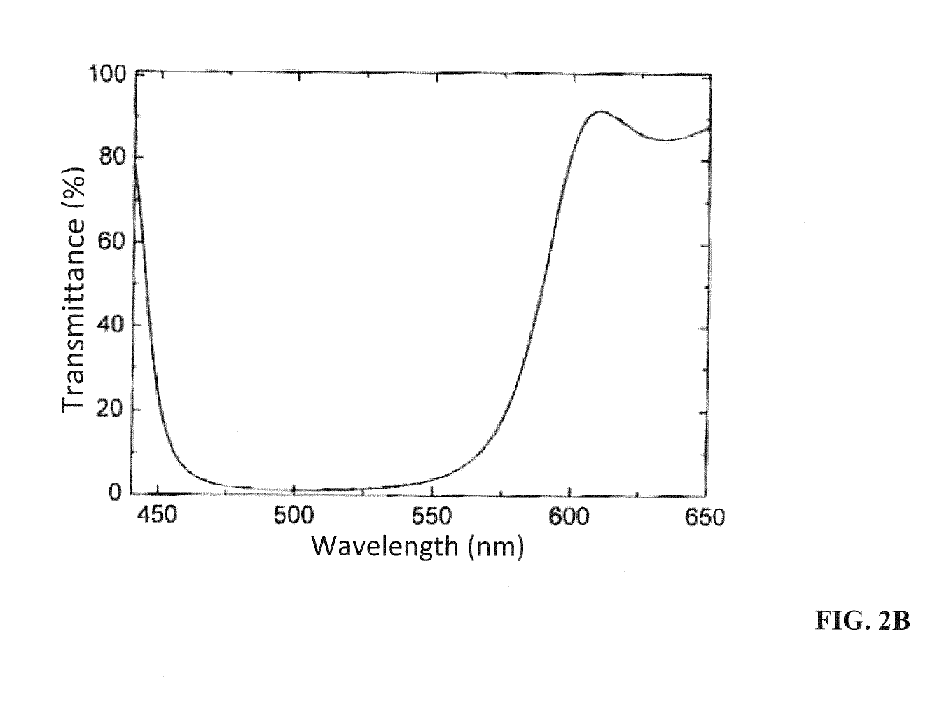

Referring to FIG. 2A, a dielectric stack mirror 100, which can be incorporated into an apparatus according to embodiments of the subject invention, can include alternating layers of dielectric material (37, 39) having different indexes of refraction (n). For example, the higher n material 37 can be Ta₂O₅, and the lower n material 39 can be SiO₂, though embodiments are not limited thereto. Each layer (37, 39) can have a thickness of from about 10 nm to about 100 nm, and there can be from 1 to 40 (in quantity) of each type of layer.

The dielectric stack mirror 100 can optionally be positioned adjacent to a glass substrate 60 and/or positioned adjacent to an electrode of the OLED, such as an ITO layer 35. In an embodiment, the dielectric stack mirror 100 can be transparent to light 21 in a certain wavelength range (or ranges), such as infrared (IR) light and/or a portion of the visible light spectrum, while reflecting light 22 of a certain wavelength range (or ranges), such as another portion of the visible light spectrum. That is, the dielectric stack mirror 100 can have a reflectivity of about 10% or <10% for light 21 in a certain wavelength range (or ranges) while having a reflectivity of about 90% or >90% for light 22 of a certain wavelength range (or ranges). For example, the dielectric stack mirror 100 can be transparent to (at least) infrared (IR) light and/or red light while reflecting (at least) green light. In a specific embodiment, the dielectric stack mirror reflects the light produced by the light emitting layer.

In certain embodiments, the dielectric stack mirror can incorporate alternating layers of Ta₂O₅ and SiO₂. Each Ta₂O₅ layer can have a thickness of, for example, from about 10 nm to about 100 nm, and each SiO₂ layer can have a thickness of, for example, from about 10 nm to about 100 nm. The dielectric stack mirror can include, for example, N layers of Ta₂O₅, wherein the number of layers of SiO₂, is in a range of from N−1 to N+1, and wherein N is in a range of from 1 to 40.

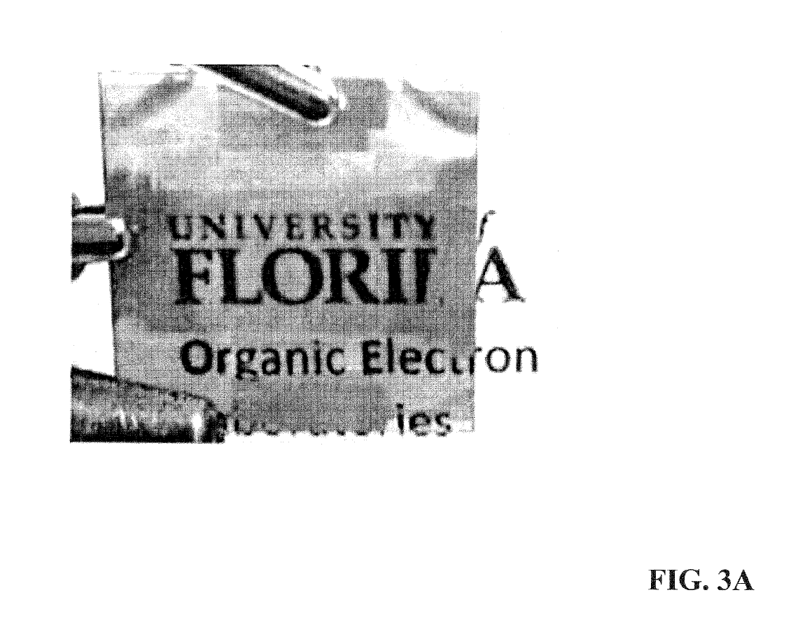

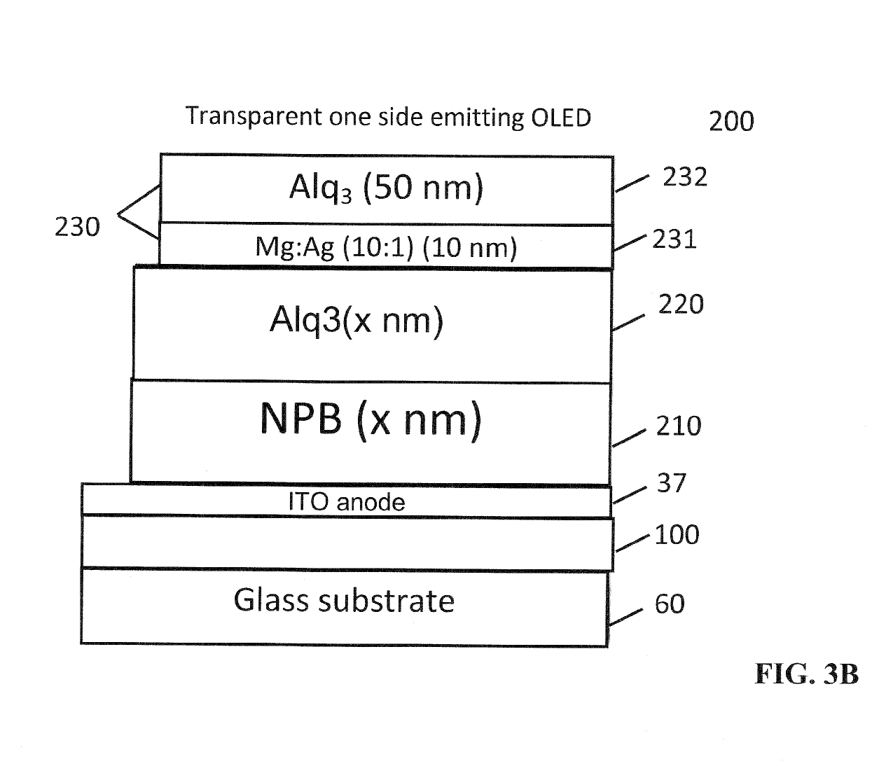

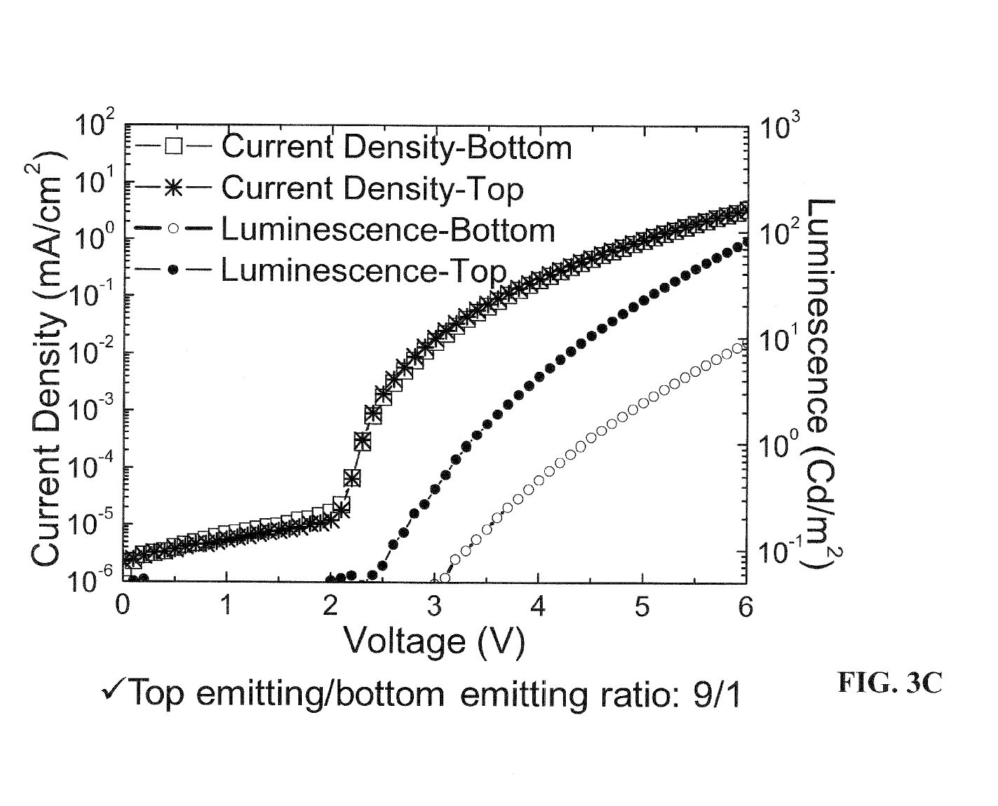

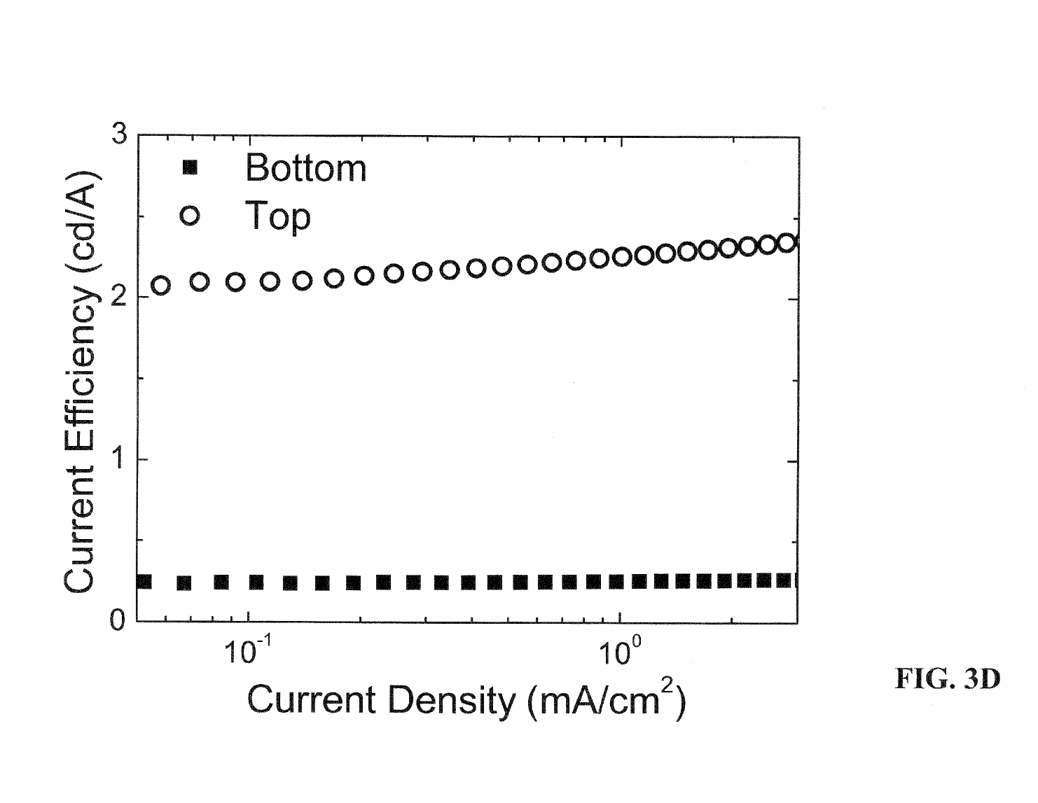

Referring to FIG. 2B, in an embodiment, the dielectric stack mirror 100 can have a reflectivity of over 98% for light having a wavelength in a range of from 475 nm to 550 nm and a transmittance of at least 80% (i.e. a reflectivity of 20% or less) for light having a wavelength of 440 nm or 600 nm. Looking through the dielectric stack mirror 100 can appear like the image in FIG. 3A, such that light passing through the dielectric stack mirror can have a light-reddish appearance, as the dielectric stack mirror is transparent for red light.

Referring to FIG. 3B, in an embodiment, an at least partially transparent and one-side emitting OLED 200 can include a mirror 100 (such as a dielectric stack mirror), a transparent anode electrode 37 on the mirror 100, an organic light-emitting layer 220 on the transparent anode electrode 37, and a transparent cathode electrode 230 on the organic light-emitting layer 220. The OLED 200 can optionally include a glass substrate 60 under the mirror 100. The OLED 200 can also optionally include a hole transporting layer 210 on the transparent anode electrode 37 and under the organic light-emitting layer 220. The OLED 200 can also optionally include an electron transporting layer (not shown).

In an embodiment, the dielectric stack minor 100 can include alternating layers of Ta₂O₅ and SiO₂. Each Ta₂O₅ layer can have a thickness of from about 10 nm to about 100 nm, and each SiO₂ layer can have a thickness of from about 10 mn to about 100 nm. The dielectric stack mirror 100 can include N layers of Ta₂O₅, wherein the number of layers of SiO₂, is a range of from N−1 to N+1, and wherein N is in a range of from 1 to 40.

The organic light-emitting layer 220 can include, for example, Iridium tris(2-phenylpyidine) (Ir(ppy)3), [2-methoxy-5-(2-ethylhexyloxy)-p-phenylenevinylene] (MEH-PPV), Tris-(8-quinolinolato)aluminum) (Alq3), and/or bis[(4,6-di-fluorophenyl)-pyridinate-]picolinate (Flrpic), though embodiments are not limited thereto. The hole transporting layer 210 can include (N,N′-di-[(1-naphthalenyl)-N,N′-diphenyl]-(1,1′-biphenyl)-4,4′-diamine) (NPB), 1,1-bis((di-4-tolylamino)phenyl)cyclohexane (TAPC), (poly(9,9-dioctylfluorene-co-N-(4-butylphenyl)diphenylamine)) (TFB), and/or diamine derivative (TPD), though embodiments are not limited thereto. The electron transporting layer (not shown) can include BCP, Bphen, 3TPYMB, and/or Alq3, though embodiments are not limited thereto. The transparent anode electrode 37 can include indium tin oxide (ITO), carbon nanotuhes (CNTs), indium zinc oxide (IZO), a silver nanowire, or a magnesium:silver/Alq3 (Mg:Ag/Alq3) stack layer, though embodiments are not limited thereto. The transparent cathode electrode 230 can include ITO, CNTs, IZO, a silver nanowire, or a Mg:Ag/Alq3 stack layer, though embodiments are not limited thereto.

In an embodiment, the transparent cathode electrode 230 can include a Mg:Ag/Alq3 stack layer. The Mg:Ag layer 231 can have a thickness of less than 30 nm. In a particular embodiment, the Mg:Ag layer 231 can have a thickness of about 10 nm. In a further embodiment, the Mg:Ag layer 231 can have a thickness of 11 nm. Mg and Ag can be present in a ratio of 10:1 (Mg:Ag) or about 10:1 (Mg:Ag). The Alq3 232 layer can have a thickness of from 0 nm to 200 nm. In a particular embodiment, the Alq3 232 layer can have a thickness of about 50 nm. In a further embodiment, the Alq3 layer 232 can have a thickness of 50 nm.

The transparent anode electrode 37, the organic light-emitting layer 220, the hole transporting layer 210 (if present), and the electron transporting layer (if present) can each have a thickness of from about 10 nm to about 500 nm. More specifically, each of these layers can have a thickness of from about 40 nm to about 200 nm. In a particular embodiment, the transparent anode electrode 37 can have thickness of about 110 nm, the organic light-emitting layer 220 can have a thickness of about 70 nm, and the hole transporting layer 210 can have a thickness of about 70 nm.

In an embodiment of the subject invention, a method of fabricating a transparent and one-side emitting OLED can include: forming a mirror; forming a transparent anode electrode on the mirror; forming an organic light-emitting layer on the transparent anode electrode; and forming a transparent cathode electrode on the organic light-emitting layer. The mirror can be, for example, a dielectric stack mirror, wherein the dielectric stack mirror includes alternating layers of two dielectric materials having different refractive indexes.

In certain embodiments, a dielectric stack mirror can include alternating layers of Ta₂O₅ and SiO₂, wherein each Ta₂O₅ layer has a thickness of from about 10 nm to about 100 nm, wherein each SiO₂ layer has a thickness of from about 10 nm to about 100 nm, wherein the dielectric stack mirror includes N layers of Ta₂O₅, wherein the number of layers of SiO₂, is a range of from N−1 to N+1, and wherein N is in a range of from 1 to 40. The dielectric stack mirror can have a reflectivity of greater than 98% for light having a wavelength in a range of from 475 nm to 550 nm, and wherein the dielectric stack mirror has a reflectivity of less than 20% for light having a wavelength of 440 nm, and wherein the dielectric stack mirror has a reflectivity of less than 20% for light having a wavelength of 600 nm.

In many embodiments, the transparent cathode electrode includes a Mg:Ag/Alq3 stack layer, and forming the transparent cathode electrode includes: forming a Mg:Ag layer at a thickness of less than 30 nm, wherein Mg and Ag are present in a ratio of 10:1 (Mg:Ag); and forming an Alq3 layer on the Mg:Ag layer at a thickness of from 0 nm to 200 nm.

According to embodiments of the subject invention, an advantageous, transparent one-side emitting OLED utilizes a mirror with a transparent anode electrode (e.g. an ITO bottom anode electrode) and a transparent cathode electrode (e.g. a thin Mg:Ag/Alq3 top cathode electrode). The mirror can have a very high (about 90% or >90%) reflectivity for light having a wavelength in a certain range (or ranges) while having a low (20% or less) reflectivity for light having a wavelength in a different range or ranges. For example, the mirror can have a reflectivity of over 98% for light having a wavelength in the range of from about 475 nm to about 550 nm and a transmittance of >80% (reflectivity of 20% or less) for light having a wavelength of about 440 nm or about 600, as shown in FIG. 2A. The mirror can be transparent to at least a portion of the visible spectrum of light, and light passing through it can have, for example, a light-reddish appearance as seen in FIG. 3A. In many embodiments, more than 90% of the light emitted from the OLED will transmit through the transparent anode electrode, and only a very small fraction (<10%) of light in certain wavelength ranges can transmit through the mirror.

In many embodiments of the subject invention, the OLED can incorporate a mirror.

The OLED can include a light emitting layer (e.g., an organic light emitting layer) which emits light having a given wavelength in the visible spectrum or having a wavelength within a range, at least a portion of which is in the visible spectrum. The mirror can reflect at least a portion of the visible light emitted by the light emitting layer of the OLED. For example, the mirror can reflect greater than 90% or at least 90% of the visible light emitted by the light emitting layer of the OLED. in various embodiments, the mirror can reflect any one of the following percentages or ranges of visible light emitted by the light emitting layer of the OLED: 90%, about 90%, >91%, 91%, about 91%, >92%, 92%, about 92%, >93%, 93%, about 93%, >94%, 94%, about 94%, >95%, 95%, about 95%, >96%, 96%, about 96%, >97%, 97%, about 97%, >98%, 98%, about 98%, >99%, 99%, about 99%, about 100%, 100%, >89%, 89%, about 89%, >88%, 88%, about 88%, >87%, 87%, about 87%, >86%, 86%, about 86%, >85%, 85%, about 85%, >84%, 84%, about 84%, >83%, 83%, about 83%, >82%, 82%, about 82%, >81%, 81%, about 81%, >80%, 80%, about 80%, >79%, 79%, about 79%, >78%, 78%, about 78%, >77%, 77%, about 77%, >76%, 76%, about 76%, >75%, 75%, about 75%, >74%, 74%, about 74%, >73%, 73%, about 73%, >72%, 72%, about 72%, >71%, 71%, about 71%, >70%, 70%, about 70%, at least 90%, at least 91%, at least 92%, at least 93%, at least 94%, at least 95%, at least 96%, at least 97%, at least 98%, at least 99%, at least 89%, at least 88%, at least 87%, at least 86%, at least 85%, at least 84%, at least 83%, at least 82%, at least 81%, at least 80%, at least 79%, at least 78%, at least 77%, at least 76%, at least 75%, at least 74%, at least 73%, at least 72%, at least 71%, or at least 70%.

The mirror can also be transparent or transmissive to at least a portion of light in the visible spectrum. For example, the mirror can be reflective of <20% (i.e., transmissive to >80%) of a portion of the visible light that does not include the portion of the visible spectrum emitted by the light emitting layer of the OLED (that is, <20% of the visible light having a wavelength in a range that does not overlap with the wavelength or wavelength range of the light emitted by the light emitting layer of the OLED). In various embodiments, the mirror can be reflective of any one of the following percentages or ranges of visible light having a wavelength or wavelength range that does not overlap with the light emitted by the light emitting layer of the OLED: 20%, about 20%, <21%, 21%, about 21%, <22%, 22%, about 22%, <23%, 23%, about 23%, <24%, 24%, about 24%, <25%, 25%, about 25%, <26%, 26%, about 26%, <27%, 27%, about 27%, <28%, 28%, about 28%, <29%, 29%, about 29%, about 0%, 0%, <19%, 19%, about 19%, <18%, 18%, about 18%, <17%, 17%, about 17%, <16%, 16%, about 16%, <15%, 15%, about 15%, <14%, 14%, about 14%, <13%, 13%, about 13%, <12%, 12%, about 12%, <11%, 11%, about 11%, <10%, 10%, about 10%, <9%, 9%, about 9%, <8%, 8%, about 8%, <7%, 7%, about 7%, <6%, 6%, about 6%, <5%, 5%, about 5%, <4%, 4%, about 4%, <3%, 3%, about 3%, <2%, 2%, about 2%, <1%, 1%, about 1%, <30%, 30%, about 30%, no more than 20%, no more than 21%, no more than 22%, no more than 23%, no more than 24%, no more than 25%, no more than 26%, no more than 27%, no more than 28%, no more than 29%, no more than 19%, no more than 18%, no more than 17%, no more than 16%, no more than 15%, no more than 14%, no more than 13%, no more than 12%, no more than 11%, no more than 10%, no more than 9%, no more than 8%, no more than 7%, no more than 6%, no more than 5%, no more than 4%, no more than 3%, no more than 2%, no more than 1%, or no more than 30%.

The mirror can be transparent or transmissive to at least a portion of light in the visible spectrum. For example, the mirror can be reflective of >80% of the entire spectrum of visible light. In various embodiments, the mirror can be reflective of any one of the following percentages or ranges of the entire spectrum of visible light: 20%, about 20%, <21%, 21%, about 21%, <22%, 22%, about 22%, <23%, 23%, about 23%, <24%, 24%, about 24%, <25%, 25%, about 25%, <26%, 26%, about 26%, <27%, 27%, about 27%, <28%, 28%, about 28%, <29%, 29%, about 29%, <30%, 30%, or about 30%, <31%, 31%, about 31%, <32%, 32%, about 32%, <33%, 33%, about 33%, <34%, 34%, about 34%, <35%, 35%, about 35%, <36%, 36%, about 36%, <37%, 37%, about 37%, <38%, 38%, about 38%, <39%, 39%, about 39%, 40%, 40%, or about 40%, <41%, 41%, about 41%, <42%, 42%, about 42%, <43%, 43%, about 43%, <44%, 44%, about 44%, <45%, 45%, about 45%, <46%, 46%, about 46%, <47%, 47%, about 47%, <48%, 48%, about 48%, <49%, 49%, about 49%, 50%, 50%, or about 50%, <51%, 51%, about 51%, <52%, 52%, about 52%, <53%, 53%, about 53%, <54%, 54%, about 54%, <55%, 55%, about 55%, <56%, 56%, about 56%, <57%, 57%, about 57%, <58%, 58%, about 58%, <59%, 59%, about 59%, 60%, 60%, or about 60%, <61%, 61%, about 61%, <62%, 62%, about 62%, <63%, 63%, about 63%, <64%, 64%, about 64%, <65%, 65%, about 65%, <66%, 66%, about 66%, <67%, 67%, about 67%, <68%, 68%, about 68%, <69%, 69%, about 69%, 70%, 70%, or about 70%, <71%, 71%, about 71%, <72%, 72%, about 72%, <73%, 73%, about 73%, <74%, 74%, about 74%, <75%, 75%, about 75%, <76%, 76%, about 76%, <77%, 77%, about 77%, <78%, 78%, about 78%, <79%, 79%, about 79%, 80%, 80%, or about 80%, <81%, 81%, about 81%, <82%, 82%, about 82%, <83%, 83%, about 83%, <84%, 84%, about 84%, <85%, 85%, about 85%, <86%, 86%, about 86%, <87%, 87%, about 87%, <88%, 88%, about 88%, <89%, 89%, about 89%, 90%, about 90%, >90%, >89%, >88%, >87%, >86%, >85%, >84%, >83%, >82%, >81%, >80%, >79%, >78%, >77%, >76%, >75%, >74%, >73%, >72%, >71%, >70%, >20%, >21%, >22%, >23%, >24%, >25%, >26%, >27%, >28%, >29%, >30%, >31%, >32%, >33%, >34%, >35, >36%, >37%, >38%, >39%, >40%, >41%, >42%, >43%, >44%, >45%, >46%, >47%, >48, >49%, >50%, >51%, >52%, >53%, >54%, >55%, >56%, >57%, >58%, >59%, >60%, >61%, >62%, >63%, >64%, >65%, >66%, >67%, >68%, >69%, at least 90%, at least 89%, at least 88%, at least 87%, at least 86%, at least 85%, at least 84%, at least 83%, at least 82%, at least 81%, at least 80%, at least 79%, at least 78%, at least 77%, at least 76%, at least 75%, at least 74%, at least 73%, at least 72%, at least 71%, at least 70%, at least 20%, at least 21%, at least 22%, at least 23%, at least 24%, at least 25%, at least 26%, at least 27%, at least 28%, at least 29%, at least 19%, at least 18%, at least 17%, at least 16%, at least 15%, at least 14%, at least 13%, at least 12%, at least 11%, at least 10%, at least 9%, at least 8%, at least 7%, at least 6%, at least 5%, at least 4%, at least 3%, at least 2%, at least 1%, at least 30%, at least 31%, at least 32%, at least 33%, at least 34%, at least 35, at least 36%, at least 37%, at least 38%, at least 39%, at least 40%, at least 41%, at least 42%, at least 43%, at least 44%, at least 45%, at least 46%, at least 47%, at least 48, at least 49%, at least 50%, at least 51%, at least 52%, at least 53%, at least 54%, at least 55%, at least 56%, at least 57%, at least 58%, at least 59%, at least 60%, at least 61%, at least 62%, at least 63%, at least 64%, at least 65%, at least 66%, at least 67%, at least 68%, at least 69%, no more than 90%, no more than 89%, no more than 88%, no more than 87%, no more than 86%, no more than 85%, no more than 84%, no more than 83%, no more than 82%, no more than 81%, no more than 80%, no more than 79%, no more than 78%, no more than 77%, no more than 76%, no more than 75%, no more than 74%, no more than 73%, no more than 72%, no more than 71%, no more than 70%, no more than 20%, no more than 21%, no more than 22%, no more than 23%, no more than 24%, no more than 25%, no more than 26%, no more than 27%, no more than 28%, no more than 29%, no more than 30%, no more than 31%, no more than 32%, no more than 33%, no more than 34%, no more than 35, no more than 36%, no more than 37%, no more than 38%, no more than 39%, no more than 40%, no more than 41%, no more than 42%, no more than 43%, no more than 44%, no more than 45%, no more than 46%, no more than 47%, no more than 48, no more than 49%, no more than 50%, no more than 51%, no more than 52%, no more than 53%, no more than 54%, no more than 55%, no more than 56%, no more than 57%, no more than 58%, no more than 59%, no more than 60%, no more than 61%, no more than 62%, no more than 63%, no more than 64%, no more than 65%, no more than 66%, no more than 67%, no more than 68%, or no more than 69%.

In an embodiment, the OLED can incorporate a mirror and can include a light emitting layer (e.g., an organic light emitting layer) that emits light, at least a portion of which is in the visible spectrum. In various embodiments, the mirror can reflect at least 80%, or at least 90%, of the visible light emitted by the light emitting layer of the OLED and can also be reflective of no more than 20% of visible light other than the light emitted by the light emitting layer of the OLED. In various embodiments, the mirror can reflect any of the values of ranges listed above of the visible light emitted by the light emitting layer of the OLED and can also be reflective of any of the values of ranges listed above for wavelength ranges of visible light that do not overlap with the wavelength range including the light emitted by the light emitting layer of the OLED.

According to an embodiment of the subject invention, an advantageous, at least partially transparent one-side emitting OLED can include a mirror, a transparent anode electrode (e.g., an ITO bottom anode electrode), a transparent cathode electrode (e.g. a thin Mg:Ag/Alq3 top cathode electrode), and an organic light emitting layer. In various embodiments, the mirror can reflect at least 80%, or at least 90%, of the visible light emitted by the organic light emitting layer and can reflect no more than 30% of the visible light other than the light emitted by the organic light emitting layer of the OLED. The mirror can be a dielectric stack mirror and can include alternating layers of two dielectric materials having different refractive indexes. The dielectric materials can be, for example, Ta₂O₅ and SiO₂.

In a further embodiment, the minor can reflect at least 80% of the visible light emitted by the organic light emitting layer and can reflect no more than 30% of the visible light other than the light emitted by the organic light emitting layer of the OLED.

In yet a further embodiment, the mirror can reflect at least 80% of the visible light emitted by the organic light emitting layer and can reflect no more than 20% of the visible light other than the light emitted by the organic light emitting layer of the OLED.

In yet a further embodiment, the mirror can reflect at least 80% of the visible light emitted by the organic light emitting layer and can reflect no more than 10% of the visible light other than the light emitted by the organic light emitting layer of the OLED.

In yet a further embodiment, the minor can reflect at least 90% of the visible light emitted by the organic light emitting layer and can reflect no more than 10% of the visible light other than the light emitted by the organic light emitting layer of the OLED.

### EXAMPLE 1

An OLED was fabricated, including: a glass substrate having a thickness of about 1 mm; a dielectric stack mirror directly on the glass substrate; a transparent anode electrode comprising ITO and having a thickness of about 110 nm directly on the dielectric stack mirror; a hole transporting layer comprising NPB and having a thickness of about 70 nm directly on the transparent anode electrode; an organic light-emitting layer comprising Alq3 and having a thickness of about 70 nm directly on the hole transporting layer; and a transparent cathode electrode comprising an Alq3 layer having a thickness of about 50 nm and a Mg:Ag layer having a thickness of about 11 nm directly on the organic light-emitting layer.

Referring to FIG. 3C, current density (mA/cm²) and luminescence (Cd/m²) are shown as a function of voltage for both the top and bottom emission of this one-sided transparent OLED. The top emitting to bottom emitting ratio for this OLED is about 9:1. The lines for current density-bottom and current density-top are nearly identical, such that they are nearly overlapping. Referring to FIG. 3D, current efficiency (cd/A) is shown as a function of current density (mA/cm²) for both the top and bottom emission of this one-sided transparent OLED.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

What is claimed is:

1. An organic light-emitting device (OLED), comprising:
an organic light emitting layer;
a mirror;
an anode electrode, wherein the anode electrode is transparent to visible light; and
a cathode electrode, wherein the cathode electrode is transparent to visible light,
wherein the organic light emitting layer is positioned between the anode electrode and the cathode electrode, and wherein the mirror is positioned such that one of the anode electrodes and the cathode electrode is between the minor and the organic light emitting layer, and
wherein the mirror is reflective of a first visible light wavelength range, wherein at least a first portion of visible light emitted by the organic light emitting layer has wavelengths within the first visible light wavelength range, and wherein the mirror is transmissive to a second visible light wavelength range, wherein the organic light emitting layer does not emit light having wavelengths in at least a portion of the second visible light wavelength range.

2. The OLED according to claim 1, wherein the visible light emitted by the organic light emitting layer has wavelengths within the first visible light wavelength range, wherein the organic light emitting layer does not emit light having wavelengths in the second visible wavelength range.

3. The OLED according to claim 1, wherein the minor comprises a dielectric stack minor.

4. The OLED according to claim 3, wherein the dielectric stack mirror has a reflectivity of greater than 98% for light having a wavelength in a range of from 475 nm to 550 nm, and wherein the dielectric stack mirror has a reflectivity of 20% or less for light having a wavelength of 440 nm, and wherein the dielectric stack mirror has a reflectivity of 20% or less for light having a wavelength of 600 nm.

5. The OLED according to claim 3, wherein the OLED further comprises a substrate, wherein the substrate is adjacent to the mirror.

6. The OLED according to claim 3 wherein the dielectric stack mirror comprises a Ta₂O₅ layer and an SiO₂ layer.

7. The OLED according to claim 6, wherein the dielectric stack mirror comprises alternating layers of Ta₂O₅ and SiO₂, wherein each Ta₂O₅ layer has a thickness of from about 10 nm to about 100 nm, and wherein each SiO₂ layer has a thickness of from about 10 nm to about 100 nm.

8. The OLED according to claim 7, wherein the dielectric stack mirror comprises N layers of Ta₂O₅, wherein the number of layers of SiO₂, is a range of from N−1 to N+1, and wherein N is in a range of from 1 to 40.

9. The OLED according to claim 1, further comprising a hole transporting layer and an electron transporting layer.

10. The OLED according to claim 1, wherein the organic light-emitting layer comprises Ir(ppy)3, MEH-PPV, Alq3, or Flrpic.

11. The OLED according to claim 9, wherein the hole transporting layer comprises NPB, TAPC, TFB, or TPD.

12. The OLED according to claim 9, wherein the electron transporting layer comprises BCP, Bphen, 3TPYMB, or Alq3.

13. The OLED according to claim 1, wherein the transparent anode comprises at least one material selected from the group consisting of: indium tin oxide (ITO), carbon nanotubes (CNTs), indium zinc oxide (IZO), a silver nanowire, and a magnesium:silver/Alq3 (Mg:Ag/Alq3) stack layer, and wherein the transparent cathode comprises at least one material selected from the group consisting of: ITO, CNTs, IZO, a silver nanowire, and a Mg:Ag/Alq3 stack layer.

14. The OLED according to claim 13, wherein the transparent cathode comprises a Mg:Ag/Alq3 stack layer, wherein the Mg:Ag layer has a thickness of less than 30 nm, and wherein Mg and Ag are present in a ratio of 10:1 (Mg:Ag), and wherein the Alq3 layer has a thickness of from 0 nm to 200 nm.

15. The OLED according to claim 1, wherein the transparent anode electrode is positioned between the mirror and the organic light emitting layer.

16. The OLED according to claim 1, wherein the transparent cathode electrode is positioned between the mirror and the organic light emitting layer.

17. The OLED according to claim 1, further comprising:
a glass substrate;
a hole transporting layer on the transparent anode electrode;
wherein the mirror comprises a dielectric stack mirror, wherein the dielectric stack mirror is positioned on the glass substrate, wherein the dielectric stack mirror comprises alternating layers of Ta₂O₅ and SiO₂;
wherein the transparent anode electrode is positioned on the dielectric stack mirror, wherein the transparent anode electrode comprises ITO;
wherein the organic light-emitting layer is positioned on the hole transporting layer; and
wherein the transparent cathode electrode is positioned on the organic light-emitting layer, wherein the transparent cathode electrode comprises a Mg:Ag/Alq3 stack layer, wherein the Mg:Ag layer has a thickness of less than 30 nm, and wherein Mg and Ag are present in a ratio of 10:1 (Mg:Ag), and wherein the Alq3 layer has a thickness of from 0 nm to 200 nm.

18. A lighting window, comprising
the OLED according to claim 17.

19. A lighting window, comprising:
a glass substrate; and
the OLED according to claim 1.

20. The OLED according to claim 1, wherein the mirror is reflective of at least 90% of the visible light emitted by the organic light emitting layer.

21. The OLED according to claim 2, wherein the mirror is reflective of at least 90% of the visible light emitted by the organic light emitting layer.

22. The OLED according to claim 2, wherein the mirror is transmissive to at least 80% of the visible light in the second visible light wavelength range.

23. The OLED according to claim 2, wherein the mirror is transmissive to at least 90% of the visible light in the second visible light wavelength range.

24. A method of fabricating an OLED, comprising:
forming a mirror;
forming a transparent anode electrode on the mirror;
forming an organic light-emitting layer on the transparent anode electrode; and
forming a transparent cathode electrode on the organic light-emitting layer,
wherein the mirror is reflective of a first visible light wavelength range, wherein at least a first portion of visible light emitted by the organic light emitting layer has wavelengths within the first visible light wavelength range, and wherein the mirror is transmissive to a second visible light wavelength range, wherein the organic light emitting layer does not emit light having wavelengths in at least a portion of the second visible light wavelength range.

25. The method according to claim 24, wherein the mirror comprises a dielectric stack mirror, and wherein the dielectric stack mirror comprises alternating layers of two dielectric materials having different refractive indexes.

26. The method according to claim 25, wherein the dielectric stack mirror comprises alternating layers of Ta₂O₅ and SiO₂, wherein each Ta₂O₅ layer has a thickness of from about 10 nm to about 100 nm, wherein each SiO₂ layer has a thickness of from about 10 nm to about 100 nm, wherein the dielectric stack mirror comprises N layers of Ta₂O₅, wherein the number of layers of SiO₂, is a range of from N−1 to N+1, and wherein N is in a range of from 1 to 40.

27. The method according to claim 24, wherein the transparent cathode comprises a Mg:Ag/Alq3 stack layer, and wherein forming the transparent cathode comprises:
forming a Mg:Ag layer at a thickness of less than 30 nm, wherein Mg and Ag are present in a ratio of 10:1 (Mg:Ag); and
forming an Alq3 layer on the Mg:Ag layer at a thickness of from 0 nm to 200 nm.

28. The method according to claim 26, wherein the dielectric stack mirror has a reflectivity of greater than 98% for light having a wavelength in a range of from 475 nm to 550 nm, and wherein the dielectric stack mirror has a reflectivity of 20% or less for light having a wavelength of 440 nm, and wherein the dielectric stack mirror has a reflectivity of 20% or less for light having a wavelength of 600 nm.

29. The method according to claim 24, wherein the visible light emitted by the organic light emitting layer has wavelengths within the first visible light wavelength range, wherein the organic light emitting layer does not emit light having wavelengths in the second visible wavelength range.

30. The method according to claim 24, wherein the mirror is reflective of at least 90% of the visible light emitted by the organic light emitting layer.

31. The method according to claim 29, wherein the mirror is reflective of at least 90% of the visible light emitted by the organic light emitting layer.

32. The method according to claim 29, wherein the mirror is transmissive to at least 80% of the visible light in the second visible light wavelength range.

33. The method according to claim 29, wherein the mirror is transmissive to at least 90% of the visible light in the second visible light wavelength range.
